(19) United States
(12) Patent Application Publication
(10) Pub. No.: US 2024/0038486 A1
(43) Pub. Date: Feb. 1, 2024

(54) METHOD AND APPARATUS FOR PREPARING SAMPLES FOR IMAGING

(71) Applicant: Taiwan Semiconductor Manufacturing Company, Ltd., Hsin-Chu (TW)

(72) Inventors: Yu-Ching Chiu, Hsinchu City (TW); Chih-Kuang Kao, Chu-pei City (TW); Huei-Wen Yang, Hsinchu (TW)

(21) Appl. No.: 18/298,031

(22) Filed: Apr. 10, 2023

Related U.S. Application Data
(60) Provisional application No. 63/393,658, filed on Jul. 29, 2022.

(51) Int. Cl. H01J 37/248; H01J 37/305; H01J 37/30; H01J 37/28

(52) U.S. Cl. CPC H01J 37/248; H01J 37/305; H01J 37/3005; H01J 37/28; H01J 2237/206; H01J 2237/31749; H01J 2237/2802; H01J 2237/20207; H01J 2237/20214; H01J 2237/024

(57) ABSTRACT

An apparatus for observing a sample using a charged particle beam includes an ion beam column configured to generate and direct an ion beam, an electron beam column configured to generate and direct an electron beam, a vacuum chamber for housing the sample, and a probe positioned in the vacuum chamber. The probe is configured to provide electrical connection between the sample and a power supply.

### PRIORITY

This claims the benefits to U.S. Provisional Application Ser. No. 63/393,658 filed Jul. 29, 2022, the entire disclosure of which is incorporated herein by reference.

### BACKGROUND

Dual beam systems, which may include imaging capability using focused ion beam (FIB) microscopy and scanning electron microscopy (SEM), are used extensively in failure analysis of semiconductor devices and for the preparation of electron-transparent specimens for transmission electron microscopy (TEM). The process of FIB lift-out is a procedure of several successive steps, where the starting point is the delivery of a wafer, identifying the area of interest on the wafer, and operating a lift-out probe inside the FIB vacuum chamber to extract a sample from the wafer, and the end point is imaging the sample with SEM and/or TEM for further investigation. There is a need in the industry to have the entire process automated, thus allowing for fast and safe processing of a lift-out sample without the need to vent the vacuum chamber or to remove the probe and sample through an airlock. Although in-situ lift-out technique has been adopted in the procedure in which a lift-out probe, typically having a tungsten needle as a probe tip, is applied to lift a lamella from a wafer and move the lamella to another sample support for further analysis, the procedure of identifying the area of interest is often performed ex-situ on a tester. One of the reasons is that to identify the area of interest, such as a hot spot or a circuit broken point on the wafer, bias voltage and/or stimulus often need to be provided to one of more probe pads on the wafer, while the existing lift-out probe is lack of the capability of providing such electrical connections. Accordingly, although existing approaches in FIB systems have been generally adequate for their intended purposes, they have not been entirely satisfactory in all respects. There is a need for a practical technique allowing lift-out probe(s) to provide electrical connections to the wafer in-situ. Fulfilling this need would significantly improve through put in wafer acceptance testing, process control monitoring, and/or failure analysis, as the entire process of FIB lift-out can be automated in the FIB vacuum chamber.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a dual beam system, in accordance with some embodiments of the present disclosure.

FIG. 2 illustrates a top view of a semiconductor wafer having testline structures, in accordance with some embodiments of the present disclosure.

FIG. 3 illustrates a cross-sectional view of a testline structures with frontside probe pads and backside probe pads, in accordance with some embodiments of the present disclosure.

FIG. 4 illustrates a lift-out probe operable to provide electrical connections to a sample loaded in a dual beam system, in accordance with some embodiments of the present disclosure.

FIG. 5 illustrates a TEM grid to which a sample is attached, in accordance with some embodiments of the present disclosure.

FIG. 6 illustrates a TEM sample being extracted from a work piece, in accordance with some embodiments of the present disclosure.

FIG. 7 illustrates a TEM sample being mounted on a TEM grid, in accordance with some embodiments of the present disclosure.

FIG. 8 illustrates a TEM sample and a TEM grid tilted and rotated for thinning the TEM sample using an ion beam, in accordance with some embodiments of the present disclosure.

FIG. 9 shows a flow chart of a method for a full in-situ lift-out procedure utilizing a lift-out probe as shown in FIG. 4, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term encompasses numbers that are within certain variations (such as +/−10% or other variations) of the number described, in accordance with the knowledge of the skilled in the art in view of the specific technology disclosed herein, unless otherwise specified. For example, the term “about 5 nm” may encompass the dimension range from 4.5 nm to 5.5 nm, 4.0 nm to 5.0 nm, etc.

The present disclosure generally relates to preparation of samples for imaging in charged particle beam systems, particularly, method and apparatus that allows a lift-out probe in a dual beam system to apply electrical connections (e.g., discharging, biasing, and/or adding stimulus) to a device under test (DUT), such as a semiconductor wafer, to assist in-situ identifying area of interest from which to lift-out a lamella for further analysis under a transmission electron microscopy (TEM) and/or a scanning transmission electron microscope (STEM).

As technology is demanding the construction of ever smaller structures in electronic, optical, and micromechanical systems, defects on the order of nanometers or tens of nanometers can adversely affect the performance of devices. Such defects are routinely examined using electron microscopes to determine and correct the cause of the defects. Defects can include contaminant particles that become embedded in a product during fabrication or a manufacturing defect, such as a bridge creating a short circuit between two closely spaced conductors that are intended to be electrically separated from each other.

Charged particle beam microscopy, such as scanning ion microscopy and electron microscopy, provides significantly higher resolution and greater depth of focus than optical microscopy to assist detect detection in the semiconductor industry. In a scanning electron microscope (SEM), a primary electron beam is focused to a fine spot that scans the surface to be observed. Secondary electrons are emitted from the surface as it is impacted by the primary electron beam. The secondary electrons are detected, and an image is formed, with the brightness at each point on the image being determined by the number of secondary electrons detected when the beam impacts a corresponding spot on the surface. Scanning ion microscopy (SIM) is similar to scanning electron microscopy, but an ion beam is used to scan the surface and eject the secondary electrons.

In a transmission electron microscope (TEM), a broad electron beam impacts the sample and electrons that are transmitted through the sample are focused to form an image of the sample. The sample must be sufficiently thin to allow many of the electrons in the primary beam to travel though the sample and exit on the opposite site. Samples are typically less than 100 nm thick.

In a scanning transmission electron microscope (STEM), a primary electron beam is focused to a fine spot, and the spot is scanned across the sample surface. Electrons that are transmitted through the work piece are collected by an electron detector on the far side of the sample, and the intensity of each point on the image corresponds to the number of electrons collected as the primary beam impacts a corresponding point on the surface.

Because a sample needs to be very thin for viewing with transmission electron microscopy (whether TEM or STEM), preparation of the sample can be delicate, time-consuming work. The term “TEM” sample as used herein refers to a sample for either a TEM or an STEM and references to preparing a sample for a TEM are to be understood to also include preparing a sample for viewing on an STEM. One method of preparing a TEM sample is to cut the sample from a work piece substrate using an ion beam. A lift-out probe (or probe for simplicity) is attached to the sample, either before or after the sample has been entirely freed from the work piece. The lift-out probe can be attached, for example, by static electricity, FIB deposition, or an adhesive. The sample, attached to the lift-out probe, is moved away from the work piece from which it was extracted and typically attached to a TEM grid using FIB deposition, static electricity, or an adhesive.

Some dual beam systems include an ion beam that can be used for extracting the sample, and an electron beam that can be used for TEM observation. In some dual beam systems, the FIB column is oriented an angle, such as 52 degrees, from the vertical and an electron beam column is oriented vertically. In other systems, the electron beam column is tilted, and the FIB column is oriented vertically or also tilted. The stage on which the sample is mounted can typically be tilted, in some systems up to about 60 degrees.

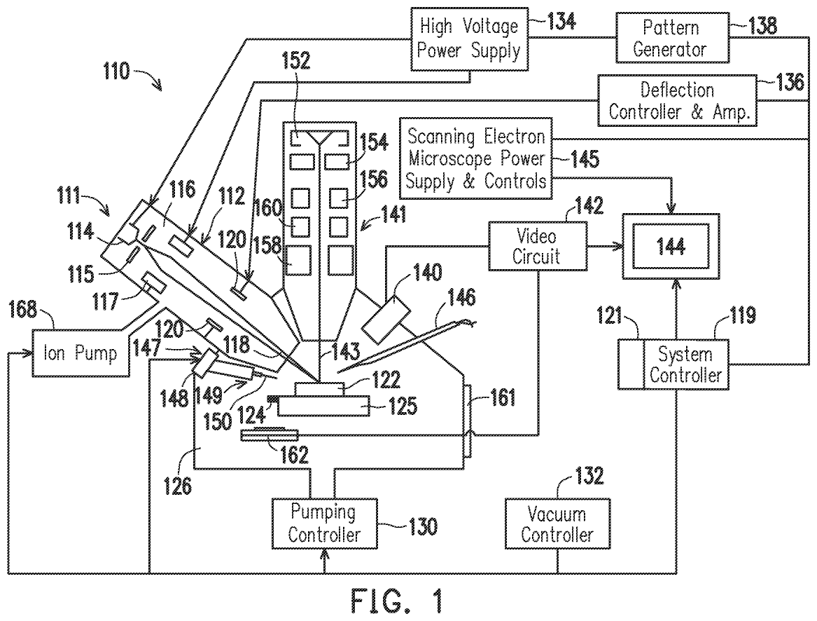

FIG. 1 shows an example dual beam system 110 in accordance with some embodiments of the present disclosure. The dual beam system 110 includes a vertically mounted electron beam column and a focused ion beam (FIB) column mounted at an angle, such as approximately 52 degrees, from the vertical. While an example of suitable hardware is provided below, the invention is not limited to being implemented in any particular type of hardware.

A scanning electron microscope 141, along with power supply and control unit 145, is provided with the dual beam system 110. An electron beam 143 is emitted from a cathode 152 by applying voltage between cathode 152 and an anode 154. Electron beam 143 is focused to a fine spot by means of a condensing lens 156 and an objective lens 158. The electron beam 143 is scanned two-dimensionally on the specimen by means of a deflection coil 160. Operation of condensing lens 156, objective lens 158, and deflection coil 160 is controlled by power supply and the control unit 145.

The electron beam 143 can be focused onto a DUT 122, such as a semiconductor wafer, which is secured on a movable stage 125 within a lower chamber 126. When the electrons in the electron beam strike the DUT 122, secondary electrons are emitted. These secondary electrons are detected by a charged particle detector 140. An STEM detector 162, located beneath a TEM sample holder 124 and the movable stage 125, can collect electrons that are transmitted through a sample mounted on the TEM sample holder 124.

The dual beam system 110 also includes a FIB system 111 which includes an evacuated chamber having an ion column 112 within which are located an ion source 114 and a focusing column 116 including extractor electrodes and an electrostatic optical system. The axis of the focusing column 116 may be tilted about 52 degrees from the axis of the electron column in some embodiments. The ion column 112 includes an ion source 114, an extraction electrode 115, a focusing element 117, deflection elements 120, and a focused ion beam 118. The focused ion beam 118 passes from the ion source 114 through the focusing column 116 and between electrostatic deflection apparatus schematically indicated at deflection plates 120 toward the DUT 122, which includes, for example, a semiconductor device positioned on the movable stage 125 within the lower chamber 126.

The movable stage 125 may also support one or more TEM sample holders 124 so that a sample can be extracted from the DUT 122 and moved to the TEM sample holder 124. The movable stage 125 can move in a horizontal plane (X and Y axes) and vertically (Z axis). The movable stage 125 can also tilt approximately sixty (60) degrees and rotate about the Z axis. In some embodiments, a separate TEM sample stage (not shown) can be used. Such a TEM sample stage may also be moveable in the X, Y, and Z axes. A door 161 is opened for inserting the DUT 122 onto the movable stage 125 and also for servicing an internal gas supply reservoir, if one is used. The door is interlocked so that it cannot be opened if the system is under vacuum.

An ion pump 168 is employed for evacuating the ion column 112. The chamber 126 is evacuated with a turbomolecular and mechanical pumping system 130 under the control of a vacuum controller 132. The vacuum system provides within the chamber 126 a vacuum of between approximately 1×10⁻⁷ Torr and 5×10⁻⁴ Torr. If an etch assisting, an etch retarding gas, or a deposition precursor gas is used, the chamber background pressure may rise, such as to about 1×10⁻⁵ Torr.

The high voltage power supply provides an appropriate acceleration voltage to electrodes in the focusing column 116 for energizing and focusing the ion beam 118. When it strikes the DUT 122, material is sputtered, that is physically ejected, from the sample. Alternatively, the ion beam 118 can decompose a precursor gas to deposit a material.

A high voltage power supply 134 is connected to the ion source 114 as well as to appropriate electrodes in the focusing column 116 for forming an approximately 1 keV to 60 keV ion beam 118 and directing the same toward the DUT 122. A deflection controller and amplifier 136, operated in accordance with a prescribed pattern provided by a pattern generator 138, is coupled to deflection plates 120 whereby the focused ion beam 118 may be controlled manually or automatically to trace out a corresponding pattern on the upper surface of the DUT 122. In some systems the deflection plates 120 are placed before the final lens. Beam blanking electrodes (not shown) within the focusing column 116 cause the ion beam 118 to impact onto blanking aperture (not shown) instead of the DUT 122 when a blanking controller (not shown) applies a blanking voltage to the blanking electrode.

The ion source 114 sometimes provides a focused ion beam 118 of gallium (Ga). The focused ion beam 118 is capable of being focused into a sub one-tenth micrometer wide beam at the DUT 122 for either modifying the DUT 122 by ion milling, enhanced etch, material deposition, or for the purpose of imaging the DUT 122.

The charged particle detector 140 for detecting secondary ion or electron emission is connected to a video circuit 142 that supplies drive signals to a video monitor 144 and receiving deflection signals from a system controller 119. The location of the charged particle detector 140 within the lower chamber 126 can vary in different embodiments. For example, the charged particle detector 140 can be coaxial with the ion beam 118 and include a hole for allowing the ion beam to pass. In other embodiments, secondary particles can be collected through a final lens and then diverted off axis for collection.

A micromanipulator 147 can precisely move objects within the vacuum chamber. The micromanipulator 147 may sometimes be referred to as nanomanipulator. The terms “micromanipulator” and “nanomanipulator” are used interchangeably in the present disclosure. The micromanipulator 147 may include precision electric motor 148 positioned outside the vacuum chamber to provide X, Y, Z, and theta control of a lift-out probe 149 positioned within the vacuum chamber. The lift-out probe 149 can be fitted with different end effectors for manipulating small objects. In the embodiments described herein, the end effector is a probe tip 150. In some embodiments, the probe tip 150 is in the form of a needle made of a metal, such as tungsten for its suitable hardness.

A gas delivery system 146 extends into the lower chamber 126 for introducing and directing a gaseous vapor toward the DUT 122. For example, iodine can be delivered to enhance etching, or a metal organic compound can be delivered to deposit a metal.

A system controller 119 controls the operations of the various parts of the dual beam system 110. Through the system controller 119, a user can cause the ion beam 118 or the electron beam 143 to be scanned in a desired manner through commands entered into a conventional user interface (not shown). Alternatively, the system controller 119 may control the dual beam system 110 in accordance with programmed instructions stored in a memory 121. In some embodiments, the dual beam system 110 incorporates image recognition software to automatically identify regions of interest, and then the system can manually or automatically extract samples in accordance with some embodiments of the present disclosure.

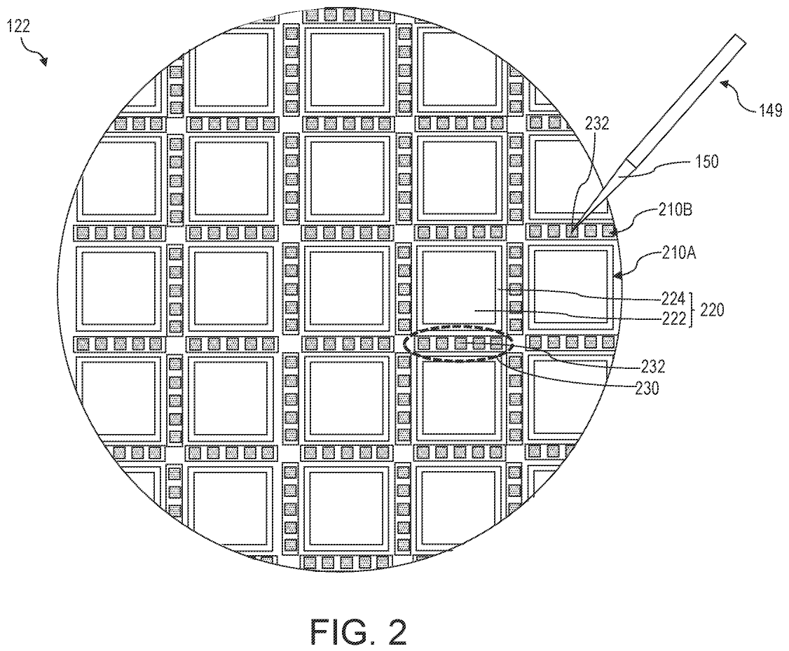

To identify regions of interest, such as a hot spot or a circuit broken point on a semiconductor wafer, bias voltages and/or stimulus may need to be applied at one or more probe pads in the DUT 122. The reference is now made to FIG. 2. FIG. 2 illustrates an example DUT 122 secured on the movable stage 125, which includes probe pads under probing from a lift-out probe 149, in accordance with some embodiments of the present disclosure.

The DUT 122 may be a semiconductor wafer having die regions 210A and scribe line regions 210B, dies 220 (including circuit region 222 and seal rings 224), and testline structures (or testlines) 230 (including probe pads 232). In some embodiments, each of the dies 220 may include integrated circuits therein and the integrated circuits may be formed by a plurality of components connected in required connection relationship to construct the specific circuits. In some embodiments, each of the dies 220 may be sealed with integrated circuits therein surrounded by the seal ring 224. The die regions 210A may refer to the regions where the dies 220 are. The scribe line regions 210B may be distributed in between the die regions 210A and may forms grid-like distribution in the semiconductor wafer. The testlines 230 may be disposed on a layout region within the scribe line regions 210B and positioned between the dies 220. The probe pads 232 are also disposed on the scribe line regions 210B.

In some embodiments, the testlines 230 may be formed on the semiconductor wafer by using the processes and steps for forming the integrated circuits in the dies 220. Accordingly, the testlines 230 and the dies 220 both include multiple components such as transistors and interconnection wiring such as redistribution layers may be formed on the semiconductor wafer for connecting the components based on the required design. After the transistors and the required wirings in the dies 220 are fabricated on the semiconductor wafer, a test such as a wafer acceptance test (WAT) may be performed on the testlines 230 to determine the acceptance rate of the semiconductor wafer. In some embodiments, the WAT may be performed before the dies 220 are completed so that the WAT may be an inter-metal WAT. In other words, after passing the inter-metal WAT, further fabrication processes may be performed on the semiconductor wafer. In some embodiments, the WAT may be performed after the first level metal layer (M1) or the second level metal layer (M2) (the former layers among the metal layers in the interconnect structure) is formed. On the contrary, if the inter-metal WAT is not passed, the semiconductor wafer may be considered as a failure wafer and no further fabrication process is performed thereon. Accordingly, the inter-metal WAT may facilitate to inspect the failure wafer in the middle stage of the fabrication process. In the wafer acceptance test, the testlines 230 may be electrically connected to an external circuit via the probe pads 232 to check the quality of the integrated circuit process. The probing is often performed through a probe card equipped on a tester ex-situ the dual beam system 110 other than in-situ with the lift-out probe 149. This is because generally a lift-out probe is merely a mechanical device without capability of providing electric connections. Further, simply wiring a lift-out probe would not serve the purpose as a lift-out probe is generally formed of a stainless-steel needle holder holding a tungsten needle, which constitutes a high-resistance path not suitable for electrical applications. On the contrary, the lift-out probe 149 is specifically designed to suit the needs of in-situ probing in a dual beam system, which is further discussed in detail later on.

Once the semiconductor wafer passes the test, the subsequent process for fabricating the final product may be performed to form the required final product. For example, the dies 220 may be packaged and singulated by cutting the semiconductor wafer along the scribe line regions 210B to obtain individual dies 220. The cutting the semiconductor wafer along the scribe line regions 210B, the singulation process, may also separate the testlines 230 from the dies 220 so that the singulated die 220 in the final product may not include the testlines 230. Alternatively, depending on the scribing width during the singulation process and location of the scribes, partial or full of the testlines 230 may remain with the singulated die 220 and is packaged together with the singulated die 220.

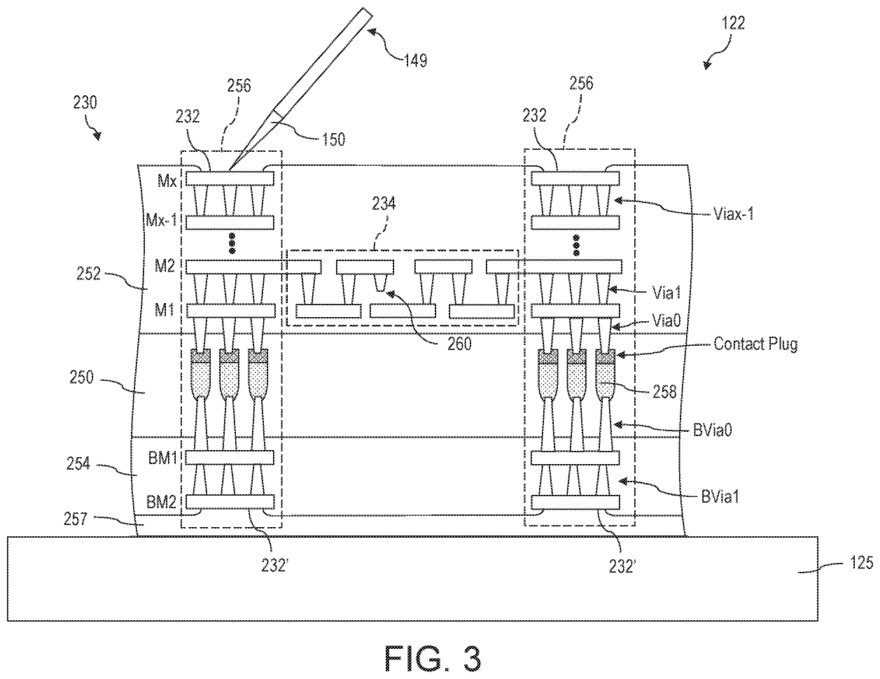

Following the continuous scale down in device feature sizes in an integrated circuit in order to meet the increasing demand of integrating more complex circuit functions on a single chip, power rails in an integrated circuit need further improvement in order to provide the needed performance boost as well as reducing power consumption. Power rails (or power routings) on a back side (or backside) of a structure, which contains transistors (such as fin field-effect transistors (FinFETs) and/or gate-all-around (GAA) transistors) in addition to an interconnect structure (which may include power rails as well) on a front side (or frontside) of the structure, is also referred to as backside power rails. The implementation of backside power rails in IC manufacturing increases the number of metal tracks available in the structure for directly powering up transistors. It also increases the gate density for greater device integration than existing structures without the backside power rails. The backside power rails may have wider dimension than the first level metal (M0) tracks on the frontside of the structure, which beneficially reduces the power rail resistance. Adopting backside power rail technology also introduce new challenges in dual beam system imaging. Reference is now made to FIG. 3, which illustrates a testline structure compatible with the backside power rail technology.

FIG. 3 illustrates a cross-sectional view of an example testline in a portion of the DUT 122, which includes two probe pads 232 associated with a circuit component 234. The bottom surface of the testline 230 is secured on the movable stage 125. This portion of the testline structure comprises a substrate layer (or semiconductor substrate) 250, a frontside insulating layer 252 formed atop the substrate layer 250, a backside insulating layer 254 formed under the substrate layer 250, and a circuit component 234 formed in the frontside insulating layer 252. Two probe pads 232 are electrically coupled to two terminals of the circuit component 234. Each probe pad 232 has an opposing backside probe pad 232′. Thus, the probe pads 132 are also referred to as frontside probe pads. The structure extending from the frontside probe pad 232 to the backside probe pad 232′ including interconnect structures therebetween is referred to as probe pad structure 256. In a probe pad structure 256, the frontside probe pad 232 is the topmost metal piece, and the backside probe pad 232′ is the bottommost metal piece. A probe pad structure 256 is separated from an adjacent probe pad structure 256. Each probe pad structure 256 includes a stacking via structure underlying the frontside probe pad 232. The stacking via structure includes a metal piece (or referred to as metal pad) on each metal layer in the same shape as the probe pads 232 and coupled to each other through one or more vias. In some embodiments, metallic materials of the frontside probe pad 232 and the metal pieces in underneath metal layers (M1, M2, . . . Mx-1) of the stacking via structure may be different. For example, the frontside probe pad 232 may include AlCu or NiPdAu—Cu, and the metal pieces in underneath metal layers may include tungsten (W), aluminum (Al), or copper (Cu).

In the illustrated embodiment, the resistance of a via formed in a first level via layer (denoted as Via 1), which is used to make electrical connection between metal layers M1 and M2, is measured through the circuit component 234. To conduct Via 1 resistance measurement with desired test precision, a via chain comprising a plurality of Via 1 is first formed between M1 and M2. Resistance of the via chain is measured and the resistance of an individual Via 1 is estimated therefrom. A via chain comprises an M2 metal piece extending from an M2 metal pad of the first probe pad structure 256, a Via 1 connecting the M2 metal piece to an M1 metal piece, and another Via 1 connecting the M1 metal piece to another M2 metal piece, and repetition of such a zig-zag pattern. The zig-zag pattern continues until an end M2 metal piece of the via chain meets an M2 metal pad of the second probe pad structure 256.

Unlike some conventional probe pad structures that is formed within the frontside insulating layer 252 only (e.g., with bottommost metal pieces starting from M1), the illustrated probe pad structure 256 includes a frontside portion formed in the frontside insulating layer 252, a backside portion formed in the backside insulating layer 254, and a middle portion formed in the substrate layer 250. The middle portion electrically connects the frontside portion and the backside portion of the probe pad structure 256. The frontside portion of the probe pad structure 256 includes a square shaped metal piece on each metal layer (e.g., M1, M2, . . . Mx-1, Mx) coupled to each other through one or more vias (e.g., Via 1, . . . Via x-1). The frontside probe pad 232 is formed on the topmost metal layer Mx. The backside portion of the probe pad structure 256 includes a square shaped metal piece on each backside meta layer (e.g., BM1, BM2) coupled to each other through one or more backside vias (e.g., BVia 1). The backside portion further includes the backside probe pad 132′ formed on the bottommost backside metal layer (e.g., BM2 in the illustrated embodiment). Thus, the probe pad structure 256 includes the frontside probe pad 232 and the backside probe pad 232′ electrically coupled to each other. In some embodiments, metallic materials of the backside probe pad 232′ and the metal pieces in other backside metal layers (e.g., BM1) may be different. For example, the backside probe pad 232′ may include AlCu or NiPdAu—Cu, and the metal pieces in BM1 may include tungsten (W), aluminum (Al), or copper (Cu).

The number of metal layers in the frontside portion of the probe pad structure 256 may be more than the number of backside metal layers in the backside portion of the probe pad structure 256. In some alternative embodiments, the number of metal layers in the frontside portion of the probe pad structure 256 may equal to the number of backside metal layers in the backside portion of the probe pad structure 256. The frontside portion is also referred to as frontside interconnect structure of the probe pad structure 256; the backside portion is also referred to as backside interconnect structure of the probe pad structure 256.

The middle portion of the probe pad structure 256 includes one or more doped epitaxial features 258, contact plugs formed atop the doped epitaxial features 258, contact vias (denoted as Via 0) connecting contact plugs and M1, and backside contact vias (denoted as BVia 0) formed under the doped epitaxial features 258 and connecting the doped epitaxial features 258 with BM1. The doped epitaxial features 258 may be source/drain features of transistors formed in a probe pad structure. Since the transistors formed in a probe pad structure do not provide circuit functions and are thus referred to as non-functional transistors. As a comparison, transistors formed as circuit components in the circuit region of a die are referred to as functional transistors. As used herein, a source/drain feature may refer to a source or a drain of a device. It may also refer to a region that provides a source and/or drain for multiple devices. The combination of contact vias Via 0, contact plugs, dope epitaxial features 258, and backside contact vias BVia0 provides an electrical connection between the frontside interconnect structure and the backside interconnect structure of the probe pad structure 256.

To protect the backside power rails (including backside probe pads), a passivation layer 257 is deposited on a bottom surface of the DUT 122. The passivation layer 257 may be formed of a dielectric material, such as undoped silicate glass (USG), silicon nitride, silicon oxide, silicon oxynitride or a non-porous material. The passivation layer 257 electrically isolates the DUT 122 from the underneath movable stage 125. The movable stage 125 is often a conductor. For DUTs without adopting backside power rail technology, it is the semiconductor substrate 250 in direct contact with the movable stage 125. Thus, charges accumulated in the DUT 122 during manufacturing processes may be easily discharged through the semiconductor substrate 250 into the movable stage 125. However, with the adopting of the backside power rail technology, in the illustrated embodiment, the DUT 122 is isolated from the movable stage 125 by the passivation layer 257. The charges accumulated in the DUT 122 during manufacturing processes may not be discharged away. The accumulated charges would interfere imaging process in a dual beam system, such as distorting a TEM image.

In the present embodiment, the specialized lift-out probe 149 is capable of providing electrical connections. In an example in-situ process, after the DUT 122 is secured on the movable stage 125, the probe tip 150 of the lift-out probe 149 is electrically connected to a ground line of a power supply. The power supply may be ex-situ to the dual beam system. By probing one of the frontside probe pad 232, the charges accumulated in the DUT 122 may be discharged to ground through the lift-out probe 149. After the accumulated charges are depleted, the probe tip 150 is switched to a voltage line of the power supply. By probing one of the frontside probe pad 232, the probe tip 150 charges up the circuit component 234. The charged portion of the circuit component 234 would be lit up in an image acquired either by focused ion beam microscopy and/or scanning electron microscopy. If there is a circuit broken point, such as a defective via 260 as illustrated in FIG. 3, the charges would not go through the defective via 260. On the acquired image, the charged portion of the circuit component 234 may appear as a bright region, and the uncharged portion of the circuit component 234 may appear as a dim region. The contrast between bright and dim regions indicates a hot spot, and thus the area of interest is identified. Alternatively, other than biasing the probe pad 232, the lift-out probe 149 may be coupled to a signal line of a signal generator to feed stimulus into the circuit component 234 and monitor the response from the circuit component 234. The signal generator may be ex-situ to the dual beam system. The power supply and the signal generator may be one equipment or two separate equipment. Further, two lift-out probes may be applied simultaneously on two probe pads on two ends of the circuit component 234 to check whether the circuit component 234 is a through. Either method, after the area of interest is identified, a lamella containing at least the circuit component 234 is ion milled. The lift-out probe 149 then ships the lamella to the TEM sample holder 124 for further investigation under TEM imaging. By adopting the specialized lift-out probe 149, The whole process including discharging a DUT, biasing and/or stimulating probe pads, identifying an area of interest, ion milling a lamella containing the area of interest, lifting out the lamella, and TEM imaging the lamella can all be performed in-situ in a dual beam system without breaking vacuum. The through put of wafer testing can be highly improved.

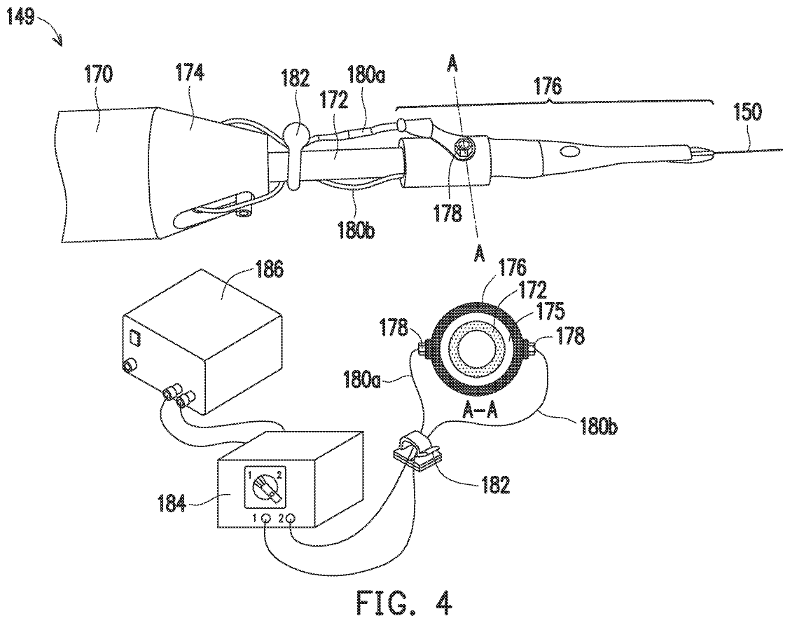

FIG. 4 illustrates an example lift-out probe (or probe) 149 in accordance with some embodiments of the present disclosure. The lift-out probe 149 includes a rod adapter 170 coupled to and driven by a precision electric motor 148 (FIG. 1). The precision electric motor 148 is positioned outside the vacuum chamber of the dual beam system 110, and the rod adapter 170 is positioned within the vacuum chamber in some embodiments. The precision electric motor 148 provides X, Y, Z, and theta control of the rod adapter 170 which passes the control eventually to the probe tip 150.

The probe tip 150 is in the form of a needle. Considering the requirement of the hardness of a probe tip being able to manipulate ion-milled samples, the probe tip 150 may essentially be made of tungsten in some embodiments. In some embodiments, to reduce electric resistance of the probe tip 150, an alloy of tungsten with a metal having resistivity lower than tungsten may be used, such as an alloy of copper-tungsten (CuW). CuW is a mixture of copper and tungsten. As copper and tungsten are not mutually soluble, the material is composed of distinct particles of one metal dispersed in a matrix of the other one. The microstructure is therefore rather a metal matrix composite instead of a true alloy. The probe tip 150 may be made from copper tungsten mixture by pressing the tungsten particles into the desired shape, sintering the compacted part, then infiltrating with molten copper. Copper tungsten mixture combines the properties of both metals, resulting in a material that is heat-resistant, ablation-resistant, highly thermally and electrically conductive, and easy to machine. Copper tungsten mixture may contain about 5% to about 50% copper in weight with the remaining portion being tungsten. Copper reduces the resistivity of the probe tip 150. The mixture with less weight percentage of copper has higher density, higher hardness, and higher resistivity. In one example, the probe tip 150 is made of 10% copper and 90% tungsten in weight. In some other embodiments, to further reduce the electric resistance of the probe tip 150, particularly to achieve lower resistance for surface current flowing through the probe tip 150, the probe tip 150 may be made of gold-plated tungsten.

The rod adapter 170 is coupled to a probe shaft (or arm) 172. The probe shaft 172 may essentially be made of stainless steel in some embodiments. A cone-shape retainer (or branch) 174 secures the probe shaft 172 to the rod adapter 170. The retainer 174 may be made of a dielectric material, such as a plastic. The end of the probe shaft 172 is embedded in a probe tip holder 176. The probe tip holder 176 has one end gripping the probe tip 150 and another end gripping the probe shaft 172. The probe tip holder 176 is electrically conducted with the probe tip 150. To reduce electric resistance of the probe tip holder 176, the probe tip holder may be formed of alloy of metals with low resistivity, such as an alloy of copper-gold (CuAu). Depending on weight percentage of gold in the alloy, the resistivity of the copper-gold alloy may be lower than 22 nΩm in some embodiments. The probe tip holder 176 is electrically insulated from the probe shaft 172. A cross-sectional view along an A—A line cutting through joints of the probe shaft 172 and the probe tip holder 176 is also illustrated in FIG. 4. In the cross-sectional view, the probe shaft 172 has a rod shape with a hollow center, and the probe tip holder 176 has a rod shape with a hollow center that embeds the probe shaft 172 with an insulator ring 175 therebetween. The insulator ring 175 may be formed of a dielectric material, such as a plastic. The insulator ring 175 electrically isolates the probe tip holder 176 from the probe shaft 172.

The probe tip holder 176 provides at least one wire connecting joint 178. In the illustrated embodiment, the probe tip holder 176 provides two wire connecting joints 178. The two wire connecting joints 178 may be positioned on opposing sides of the probe tip holder 176. The wire connecting joints 178 secure electric wires 180a and 180b to be in electrical connection with the external surface of the probe tip holder 176. A wire buncher 182 organizes the wire routing of the electric wires 180a and 180b. The wire buncher 182 is attached to the probe shaft 172. The electric wires 180a and 180b are further arranged inside the retainer 174 and guided out of the vacuum chamber. Alternatively, without a need for the wire buncher 182, the electric wires 180a and 180b may be arranged internally through the hollow tube of the probe shaft 172 to be guided into the retainer 174 and eventually out of the vacuum chamber.

Out of the vacuum chamber, the electric wires 180a and 180b are connected to a switch control box 184. The switch control box 184 controls connections between the electric wires 180a and 180b and a power supply (or a stimulus source) 186. For example, the electric wire 180a may function as a grounding wire connecting to a ground line of the power supply 186, and the electric wire 180b may function as a biasing wire connecting to a voltage line of the power supply 186. After a DUT is secured on a movable stage in the vacuum chamber, the probe tip 150 lands on a probe pad of the DUT to discharge accumulated charges. Meanwhile, the switch control box 184 actives the connection between the electric wire 180a and the ground line of the power supply 186 and puts the electric wire 180b on electrical floating. The charges on the DUT are discharged through a path comprising the probe tip 150, the probe tip holder 176, the electric wire 180a, and the ground line of the power supply 186. After the discharging, the switch control box 184 actives the connection between the electric wire 180b and the voltage line of the power supply 186 and puts the electric wire 180a on electric floating. A bias voltage is applied to a probe pad of the DUT through a path comprising the voltage line of the power supply 186, the electric wire 180b, the probe tip holder 176, and the probe tip 150. The bias voltage's amplitude may be tunable, such as from about 0.1 Volt to about 20 Volt, by turning a nob on the power supply 186. In some applications, it is signal stimulus provided to the DUT, and the electric wire 180a may provide stimulus into the DUT and the electric wire 180b may retrieve response from the DUT. After the area of interest is identified, the switch control box 184 cuts electric connections to both the electric wires 180a and 180b, making the probe tip 150 electric floating, which allows the un-biased probe tip 150 to be function as a normal lift-out probe tip for subsequent lifting operations in a dual beam system. Notably, providing electrical connections to a DUT through the probe tip 150 is a different issue than applying an electric charge to a probe to control the attraction between a sample and the probe. The latter is a mechanical issue by enhancing the force of attraction, which does not provide electrical functions (e.g., discharging, biasing, and/or stimulating) to a sample.

The full in-situ FIB lift-out procedure brings other advantages besides a higher through-put testing efficiency. The probe tip 150 is usually smaller than other probe tips equipped in a probe card of an ex-situ tester, which allows the probe pads of a testline structure to be smaller and saves more area for accommodating circuit regions. In some embodiments, a probe pad for in-situ probing may have a size around 10 um×10 um, which is generally smaller than those for the ex-situ probing. Further, the probe tip 150 usually leaves a smaller probe mark than using other probe tips equipped in a probe card of an ex-situ tester. In some embodiments, a probe mark left by the probe tip 150 is generally smaller than about 5 um×5 um.

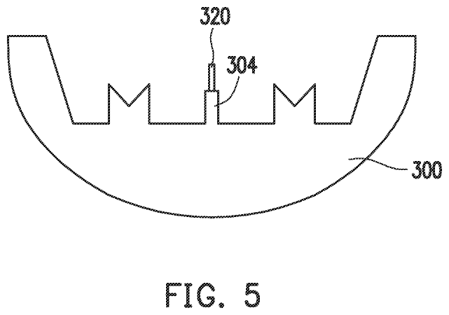

FIG. 5 shows a TEM grid 300 in accordance with some embodiments of the present disclosure. In the illustrated embodiment, the TEM grid 300 includes a partial circular ring. In some applications, a sample 302 is attached to a finger 304 of the TEM grid 300 by ion beam deposition or an adhesive. The sample 302 may be a lamella containing an area of interest, such as the circuit component 234 with a hot spot 260 as illustrated in FIG. 3. The sample 302 extends from the finger 304 so that an electron beam will have a free path through the sample 302 to a detector under the sample. TEM samples can be broadly classified as “plan view” samples or “cross sectional view” samples, depending on how the sample was oriented on the work piece. If the face of the sample to be observed was parallel to the surface of the work piece, the sample is referred to as a “plan view” sample. If the face to be observed was perpendicular to the work piece surface, the sample is referred to as a “cross-sectional view” sample. The TEM grid 300 may be mounted horizontally onto the TEM sample holder 124 (FIG. 1) in the TEM with the plane of the TEM grid perpendicular to the electron beam, and the sample is observed.

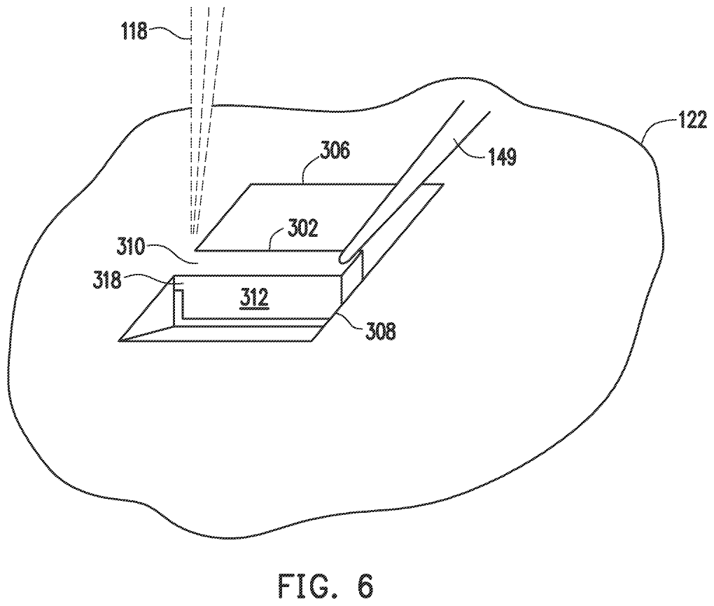

FIG. 6 shows a perspective view of a TEM sample 302 that is partly extracted from a DUT 122 using a FIB lift-out process. An ion beam 118 cuts trenches 306 and 308 on both side of sample to be extracted, leaving a thin lamella 310 having a major surface 312 that will be observed by an electron beam. The sample 302 is then freed by tilting the DUT 122 in relation to an ion beam, and cutting around its sides and bottom. The lift-out probe 149 attaches to the top of the sample 302, before or after it is freed, and transports the sample to a TEM grid. FIG. 6 shows sample 302 almost entirely freed, remaining attached by a tab 318 on one side. FIG. 6 shows an ion beam 118 ready to sever the tab 318.

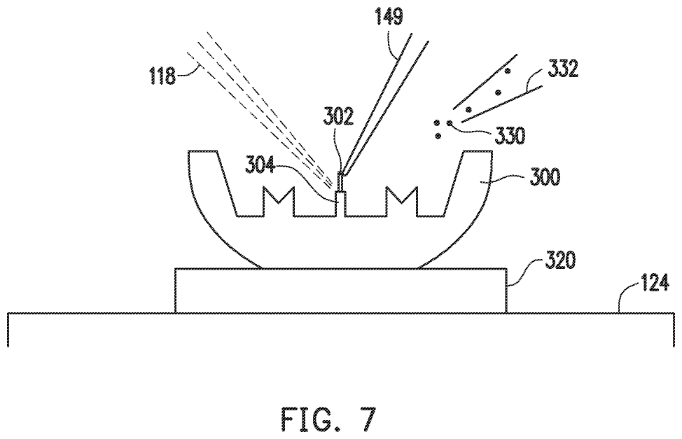

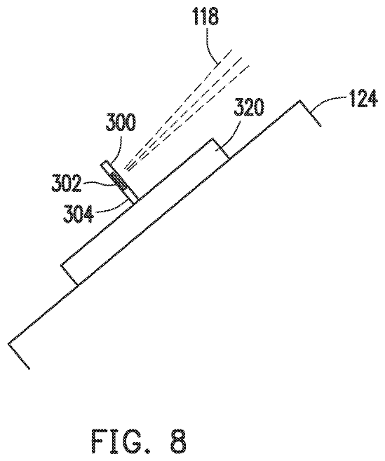

As shown in FIG. 6, the major surface 312 is oriented vertically. Transporting the lamella typically does not change its orientation, so its major surfaces are still oriented vertically when the sample 302 is brought to a TEM sample holder 124. The plane of the TEM grid 300 may be oriented vertically as shown in FIG. 7, so that the sample 302 can be attached to the finger 304 of the TEM grid 300 in such a way that major surface 312 extends parallel to the plane of the grid, and the grid structure will not interfere with the transmission of electrons when the grid is mounted on a TEM sample holder. The ion beam can be used to attach the extracted sample to the TEM grid by ion beam deposition. Once attached, the face of the sample 302 can also be thinned using the ion beam. FIG. 7 shows the sample 302 being attached to the TEM grid 300 in a grid support 320 on the TEM sample holder 124. The sample 302 is attached to the TEM grid 300 using an ion beam 118 and a deposition precursor gas 330 from a nozzle 332. FIG. 8 shows that the TEM sample holder 124 is rotated and tilted so that the sample 302 is substantially perpendicular to the ion beam 118 so that the sample 302 can be thinned by the ion beam 118.

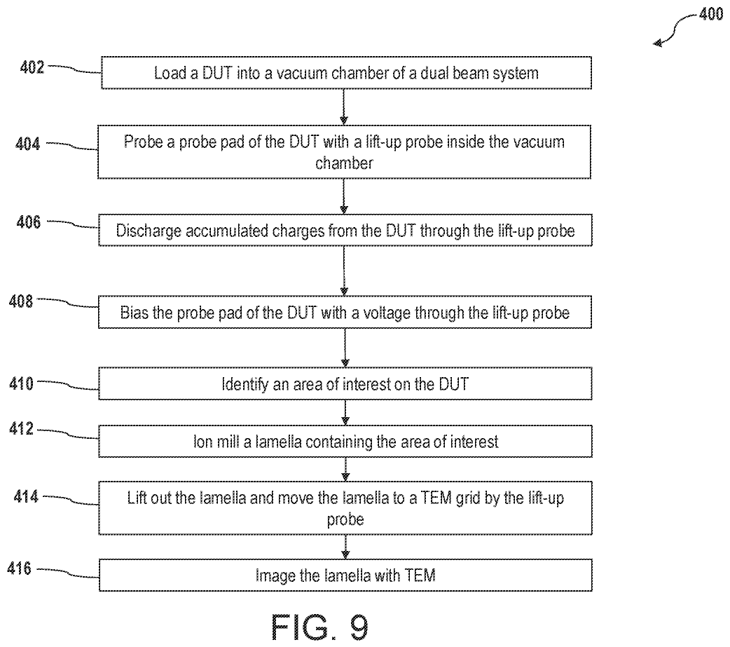

FIG. 9 is a flow chart of a method 400 for a full in-situ FIB lift-out procedure utilizing a lift-out probe that can provide electrical connections to a DUT, according to various embodiments of the present disclosure. Additional processing is contemplated by the present disclosure. Additional operations can be provided before, during, and after method 400, and some of the operations described can be moved, replaced, or eliminated for additional embodiments of method 400.

At operation 402, the method 400 loads a DUT, such as a semiconductor (e.g., silicon) wafer, into a vacuum chamber of a dual beam system. The DUT is secured on a movable stage. The atmosphere is then pumped out of the vacuum chamber so that the DUT is within a vacuum. At operation 404, the method 400 probes one or more probe pads of the DUT with one or more lift-out probes in-situ in the vacuum chamber. The one or more probe pads may be part of testline structures of the DUT. The dimension of the probe pads may be around 10 um×10 um. Probe marks left by the lift-up probes may be less than about 5 um×5 um. At operation 406, the method 400 connects the probe tip of the lift-out probe to a ground line through a switch control box, which allows charges accumulated in the DUT to be discharged through the lift-out probe. At operation 408, the method 400 connects the probe tip of the lift-out probe to a voltage line through the switch control box, which allows circuit components in the DUT to be biased or charged up to a reference voltage. In some embodiments, it is stimulus sent into the circuit components in the DUT through the probe tip. At operation 410, the method 400 identifies an area of interest (e.g., a hot spot) on the DUT by imaging the DUT under bias or stimulus with focused ion beam microscopy and/or scanning electron microscopy. At operation 412, the method 400 ion mills a lamella containing the area of interest by using a focused ion beam. During the ion milling, the lift-out probe is set to electric floating by the switch control box. At operation 414, the method 400 lifts out the lamella by the lift-out probe and positions the lamella on a TEM grid. The lamella may be further thinned down by the focused ion beam to make its thickness suitable for TEM imaging. At operation 416, the method 400 acquires TEM image of the lamella for further investigation.

The present disclosure provides a lift-out probe in a dual beam system. The lift-out probe is capable of providing electrical connections (e.g., discharging, biasing, and/or stimulating) to a DUT under probing beside regular lift-out operations. The lift-out probe allows the whole FIB lift-out procedure to be carried out in-situ a dual beam system without relying on an ex-situ tester to identify area of interest of a DUT. Accordingly, through-put of wafer examination processes can be highly increased.

In one example aspect, the present disclosure is directed to an apparatus for observing a sample using a charged particle beam. The apparatus includes an ion beam column configured to generate and direct an ion beam, an electron beam column configured to generate and direct an electron beam, a vacuum chamber for housing the sample, and a probe positioned in the vacuum chamber. The probe is configured to provide electrical connection between the sample and a power supply. In some embodiments, the ion beam column is also configured to ion mill a lamella from the sample, and the probe is also configured to lift out the lamella from the sample. In some embodiments, the probe includes a probe tip, a probe tip holder electrically connected with the probe tip, and a probe shaft coupled to the probe tip holder. In some embodiments, the probe shaft is electrically insulated from the probe tip holder. In some embodiments, the probe shaft is electrically insulated from the probe tip holder by a dielectric ring stacked between the probe shaft and the probe tip holder. In some embodiments, the probe tip includes tungsten, and the probe tip holder is free of tungsten. In some embodiments, the probe tip holder includes an alloy of copper and gold. In some embodiments, the probe shaft includes stainless steel. In some embodiments, the probe further includes at least an electric wire attached to the probe tip holder, the electric wire being electrically coupled to the power supply. In some embodiments, the apparatus further includes an electric motor configured to move and rotate the probe, the electric motor being positioned outside of the vacuum chamber.

In another example aspect, the present disclosure is directed to a probe structure for charged particle beam microscopy. The probe structure includes a needle, a needle holder gripping the needle, the needle holder being electrically connected to the needle, an electric wire attached to the needle holder, the electric wire providing electrical connection between the needle holder and a power supply, and an elongated shaft coupled to the needle holder, the elongate shaft passing movement control to the needle through the needle holder. In some embodiments, the elongated shaft is electrically insulated from the needle holder. In some embodiments, the elongated shaft is partially embedded in the needle holder. In some embodiments, the needle and the needle holder include different conductive material compositions. In some embodiments, the electric wire is a first electric wire, and the probe structure further includes a second electric wire attached to the needle holder. In some embodiments, the probe structure further includes a wire buncher configured to organize the first and second electric wires, the wire buncher being attached to the elongated shaft. In some embodiments, the needle is operable to lift out a lamella from a sample to examine under the charged particle beam microscopy.

In yet another example aspect, the present disclosure is directed to a method of observing a defect in a sample. The method includes loading the sample on a stage, probing the sample with a probe, electrically connecting the probe to a ground line to discharge the sample, electrically connecting the probe to a voltage line to bias the sample, identifying a region having the defect, ion milling the sample to free the region from the sample, and lifting out the region by the probe. In some embodiments, the sample includes an integrated circuit having frontside and backside power rails. In some embodiments, the probe includes a needle, a needle holder holding the needle, a first electric wire attached to the needle holder and providing electrical coupling between the needle holder and the ground line, and a second electric wire attached to the needle holder and providing electrical coupling between the needle holder and the voltage line.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. An apparatus for observing a sample using a charged particle beam, comprising:
an ion beam column configured to generate and direct an ion beam;
an electron beam column configured to generate and direct an electron beam;
a vacuum chamber for housing the sample; and
a probe positioned in the vacuum chamber, wherein the probe is configured to provide electrical connection between the sample and a power supply.

2. The apparatus of claim 1, wherein the ion beam column is also configured to ion mill a lamella from the sample, and the probe is also configured to lift out the lamella from the sample.

3. The apparatus of claim 1, wherein the probe includes:
a probe tip;
a probe tip holder, wherein the probe tip holder is electrically connected with the probe tip; and
a probe shaft coupled to the probe tip holder.

4. The apparatus of claim 3, wherein the probe shaft is electrically insulated from the probe tip holder.

5. The apparatus of claim 4, wherein the probe shaft is electrically insulated from the probe tip holder by a dielectric ring stacked between the probe shaft and the probe tip holder.

6. The apparatus of claim 3, wherein the probe tip includes tungsten, and the probe tip holder is free of tungsten.

7. The apparatus of claim 6, wherein the probe tip holder includes an alloy of copper and gold.

8. The apparatus of claim 6, wherein the probe shaft includes stainless steel.

9. The apparatus of claim 3, wherein the probe further includes:
at least an electric wire attached to the probe tip holder, wherein the electric wire is electrically coupled to the power supply.

10. The apparatus of claim 1, further comprising:
an electric motor configured to move and rotate the probe, wherein the electric motor is positioned outside of the vacuum chamber.

11. A probe structure for charged particle beam microscopy, comprising:
a needle;
a needle holder gripping the needle, wherein the needle holder is electrically connected to the needle;
an electric wire attached to the needle holder, wherein the electric wire provides electrical connection between the needle holder and a power supply; and
an elongated shaft coupled to the needle holder, wherein the elongate shaft passes movement control to the needle through the needle holder.

12. The probe structure of claim 11, wherein the elongated shaft is electrically insulated from the needle holder.

13. The probe structure of claim 11, wherein the elongated shaft is partially embedded in the needle holder.

14. The probe structure of claim 11, wherein the needle and the needle holder include different conductive material compositions.

15. The probe structure of claim 11, wherein the electric wire is a first electric wire, the probe structure further comprising:
a second electric wire attached to the needle holder.

16. The probe structure of claim 15, further comprising:
a wire buncher configured to organize the first and second electric wires, wherein the wire buncher is attached to the elongated shaft.

17. The probe structure of claim 11, wherein the needle is operable to lift out a lamella from a sample to examine under the charged particle beam microscopy.

18. A method of observing a defect in a sample, comprising:
loading the sample on a stage;
probing the sample with a probe;
electrically connecting the probe to a ground line to discharge the sample;
electrically connecting the probe to a voltage line to bias the sample;
identifying a region having the defect;
ion milling the sample to free the region from the sample; and
lifting out the region by the probe.

19. The method of claim 18, wherein the sample includes an integrated circuit having frontside and backside power rails.

20. The method of claim 18, wherein the probe includes:
a needle;
a needle holder holding the needle;
a first electric wire attached to the needle holder and providing electrical coupling between the needle holder and the ground line; and
a second electric wire attached to the needle holder and providing electrical coupling between the needle holder and the voltage line.
